(19) United States
(12) Patent Application Publication
(10) Pub. No.: US 2011/0247691 A1
(43) Pub. Date: Oct. 13, 2011

(54) OPTICAL SPECTRAL CONCENTRATOR, SENSORS AND OPTICAL ENERGY POWER SYSTEMS

(75) Inventors: Paul Kit Lai Yu, San Diego, CA (US); Winnie Victoria Wei-Ning Chen, La Jolla, CA (US)

(73) Assignee: THE REGENTS OF THE UNIVERSITY OF CALIFORNIA, Oakland, CA (US)

(21) Appl. No.: 13/125,519

(22) PCT Filed: Oct. 23, 2009
(86) PCT No.: PCT/US2009/061795

§ 371 Date: Jun. 8, 2011

Related U.S. Application Data
(60) Provisional application No. 61/108,050, filed on Oct. 24, 2008.

(51) Int. Cl. H01L 31/0232; H01S 5/34; B82Y 20/00

(52) U.S. Cl. 136/259; 359/344; 977/755; 977/932

(57) ABSTRACT

Methods and devices of the invention perform an optical concentration by an expansion of usable spectral width of the incident energy. Preferred methods and devices of the invention concentrate optical energy by tuning it into a narrow spectral width to match the bandgap of another system component, such as an optical fiber, an optical sensor or a photovoltaic device that converts the optical energy. Embodiments of the invention include methods and devices for the spectral concentration of multi-wavelength light and subsequent transport of the concentrated output light.

### PRIORITY CLAIM AND REFERENCE TO RELATED APPLICATION

The application claims priority under 35 U.S.C. §119 from prior provisional application Ser. No. 61/108,050, which was filed on Oct. 24, 2008.

### FIELD

A field of the invention is energy conversion, which includes both the conversion of optical radiation into electrical energy in photodetectors and photovoltaics, and the conversion of light of a given energy or wavelength into light of a different wavelength (wavelength conversion). Another field of the invention is optical sensing. Another field of the invention is power delivery.

### BACKGROUND

The energy grid of the U.S. and other countries is based upon the conversion of some form of energy into electrical power at a power plant and then the distribution of the electrical energy over the power grid that consists of electrical conductors, transformers, switching stations, etc. The “green” movement has sought to increase reliance on non-carbon emitting power plants, e.g., windmill farms and solar panels. Solar panels have been adapted to individual uses, such as by homeowners and businesses, and have also been proposed to collect large amounts of solar power at a central location. In solar panels, the incident radiation is converted by solar cells into electricity, and then that electricity is distributed by the conventional model used for other types of power plants. Most recent research has been directed toward increasing the efficiency of conversion of the solar cells used in solar panels.

Solar cells use layers of semiconductors, with structures typically described in terms of p-i-n junctions, to absorb photons of sunlight and convert them into electric current. A given semiconductor can however only convert photons larger than a specific energy, i.e., that of its bandgap (e.g., 1.1 eV in crystalline Si and 1.4 to 2.3 eV in InGaAsP family) thus limiting its efficiency (e.g., 25% for crystalline Si). One solution to this problem is to stack different semiconductors together to form multi-junction solar cells (30% efficiency to maximum 50% predicted). Solar cells made of silicon, on the other hand, are desirable despite their relatively small efficiencies because of the widespread availability of silicon and its lesser cost.

A more recent approach is used in system referred to as concentrator photovoltaic systems, which use multiple quantum wells in the intrinsic region of a p-i-n solar cell to provide a photon recycling effect and reduce radiative carrier recombination. See, e.g., D. C. Johnson, “Observation of Photon Recycling in Strain-Balanced Quantum Well Solar Cells,” Applied Physics Letters 90, 213505 (2007). This can increase the photocurrent and cell efficiency up to the point but likely below a theoretical limit. See, C. H. Henry “Limiting Efficiencies of Ideal Single and Multiple Energy Gap Terrestrial Solar Cells,” Journal of Applied Physics, 51, 4494 (1980). Multi-junction and multiple quantum well solar cells have been proposed with optical concentrators, e.g., parabolic reflectors and Fresnel lenses, that increase the photon flux incident on the solar cell to maximize the output photocurrent.

Photovoltaics would benefit greatly from further innovations that increase efficiencies or reduce costs. Increases in efficiency can make energy conversion devices produce more energy for a given footprint, or produce a comparable or even better amount of energy conversion in a smaller footprint. Apart from photovoltaics, any optoelectronic device that senses radiation is most efficient when all of the radiation matches the bandgap of the optoelectronic device. Unfortunately, many optoelectronic device operate in environments where a substantial part of incident energy falls outside of the desired spectral band.

### SUMMARY OF THE INVENTION

Methods and devices of the invention perform an optical concentration by an expansion of usable spectral width of the incident energy. Preferred methods and devices of the invention concentrate optical energy by tuning it into a narrow spectral width to match the bandgap of another system component or combination of components, such as an optical fiber, an optical sensor or a photovoltaic device that converts the optical energy. Embodiments of the invention include methods and devices for the spectral concentration of multi-wavelength light and subsequent transport of the concentrated output light.

### BRIEF DESCRIPTION OF THE DRAWINGS

FIG. 1 is a schematic diagram that illustrates a preferred embodiment spectral concentrator device of the invention;

FIG. 2 illustrates a preferred embodiment optical power system of the invention;

FIG. 3 illustrates a preferred embodiment slab waveguide and quantum well structure of the invention;

FIG. 4 is an energy band diagram for a quantum well region;

FIG. 5 is an energy band diagram for a quantum well region for a preferred embodiment spectral concentrator device of the invention.

### DETAILED DESCRIPTION OF THE PREFERRED EMBODIMENTS

Methods and devices of the invention perform an optical concentration by an expansion of usable spectral width of the incident energy. Preferred methods and devices of the invention concentrate optical energy by tuning it into a narrow spectral width to match the bandgap of another system component, such as an optical fiber, an optical sensor or a photovoltaic device that converts the optical energy. Embodiments of the invention include methods and devices for the spectral concentration of multi-wavelength light and subsequent transport of the concentrated output light. Spectral concentration, as used herein, refers to the conversion of broad-spectrum optical radiation (e.g., sunlight ranging from far infrared to ultraviolet) into light of wavelengths within a narrow spectral width.

A preferred embodiment of the invention is an integrated optical spectral concentrator device having a waveguide and an active region including a quantum well region in a region of small electric field, the quantum well region being configured to convert broad band optical radiation into electron-hole pairs and amplify seed laser. The quantum well region preferably includes multiple quantum wells. The multiple quantum well regions have bandgaps that preferably cover a majority of the solar spectrum, and preferably most of the solar spectrum. The larger the number of wells the higher the absorption, and therefore the higher the internal quantum efficiency. For multiple quantum wells in an intrinsic region (i-region), a larger number of wells could also help keep the E-field low. There is a trade-off, however, because more wells require more pump power (more concentrated solar power) to make the quantum wells transparent to a seed laser.

A preferred embodiment of the invention is an integrated optical spectral concentrator device having a waveguide for confining optical energy. The device also has a quantum well region for converting optical radiation into electron and hole pairs and permitting stimulated decay in the presence of a seed laser photon of energy to generate photons in the much narrower spectral width of the seed laser in a propagation direction close to that of the incident laser photons.

A preferred embodiment method for concentrating optical radiation receives optical radiation in a quantum well region that will convert received broadband optical radiation into electron and hole pairs. The quantum well region also receives narrow band seed optical energy. The narrow band seed optical energy is combined with recombined electron and hole pairs in the quantum well region to produce narrow band amplified optical energy. The narrow band amplified optical energy is outputted.

Light of a predetermined wavelength range through the contribution of photons is produced by stimulated emissions in the multiple quantum well region into optical energy of a predetermined band. The device preferable includes electrodes for biasing the active region, optics for directing seed laser light to the active region, and optics for coupling light output from the device to an optical fiber or optical fiber network.

Preferred embodiment methods of the invention provide an optical spectral concentrator that converts incident optical radiation, e.g., sun light, to optical energy having narrow spectral width. The narrow spectral width optical energy is coupled into an optical fiber and is routed via an optical grid to users. Optical energy is outputted to a user and can be used in the form of optical energy or can be converted to electrical or heat energy at remote locations away from direct sunlight.

A preferred application of the invention is a power system. In a preferred power system of the invention, optical radiation is concentrated into a spectral band of a large capacity optical fiber, is delivered optically (in some cases to a remote application) and then used directly, such as for lighting, or converted into heat or electricity.

In the example of solar conversion for providing electrical energy, preferred methods and device of the invention depart from the conventional approach due to the inefficiencies inherent in the use of broad spectrum sunlight with selectively absorbing photovoltaics materials. Rather than attempting to expand the photon spectrum absorbable by the solar cells, methods and devices of the invention turn the incident sunlight (or other radiation energy) into a narrow spectral width. The narrow spectral width can be matched with the bandgap(s) of phovoltaics used to convert the energy to electricity. Also, the narrow spectral width can be tuned to match the bandwidth of an optical distribution medium or system, e.g., large capacity optical fibers that can transport the narrow spectral width energy that is concentrated. A spectral concentrator of the invention can convert the received optical radiation over a predetermined narrow spectral range that is suitable for coupling to optical fibers for transport over a substantial distance to the application sites. This solar spectral concentrator and optical transport technology can be used in conjunction with efficient photovoltaic systems and enhance its performance. Systems of the invention can provide an optical power grid, remote solar illuminations for residential applications, agriculture, etc., and remote heating of building structures etc.

Vast networks of optical fibers exist in the communication infrastructure. Devices of the invention can take advantage of the components that were developed for that infrastructure, including low loss fibers and the technology for their installation in conduits in building structures. Providing solar energy through such optical fiber networks can be accomplished with systems and devices of the invention. Optical spectral concentrator devices, methods and optical transport systems of the invention can be used in conjunction with efficient photovoltaic cells and an optical power grid to provide remote solar illuminations for agriculture and remote warming of building structures etc.

In the example of sunlight impinging upon a spectral concentrator device of the invention, the net result is that broad spectrum solar radiation is concentrated within a few wavelength regions in the form of stimulated amplified light. This output light can be routed through optical fiber(s) and used, for example, to irradiate photovoltaics with bandgaps matching the concentrated output spectral width, thus augmenting the photocurrent and solar cell efficiency. Other applications of the spectrally concentrated, fiber-transported output light include optical power grids, remote solar illumination for agriculture and remote warming of building structures. Such embodiments of the invention address a need in the photovoltaic industry for higher efficiency conversion of solar photon energy—which is distributed across a broad spectrum (approximately 300 nm to 3000 nm, or 0.4 to 4 eV)—into electrical form.

A preferred method of spectral concentration uses auxiliary laser planar optics so that amplified spectrally concentrated output light emerges edgewise, i.e., from edge facets of a waveguide. A preferred device geometry couples with optical fiber that can deliver the light to be used directly, to be delivered remotely and/or to be directed at a photo to electric converter, e.g., a solar cell or an array of solar cells. Transport of the energy via an optical fiber prior to its conversion into electrical power provides many benefits, including lower heat loads on solar cells because the solar cells can be installed away from the incident solar light, such as indoors. This leaves many options for the placement of the solar cells. In preferred power systems of the invention, optical fiber networks are employed for distribution to remote locations.

Preferred embodiment optical concentration devices contains multiple quantum wells. An auxiliary light source or sources (e.g., lasers) that emit at the energies of the radiative transitions characteristic of the multiple quantum wells assist a stimulated decay mechanism with a distribution of photons in a predetermined narrow spectral range of interest. The multiple quantum wells are designed so that photo-generated electrons and holes that accumulate and relax within the multiple quantum well conduction and valence bands have overlapping envelope wave functions, which in turn favor the occurrence of photon-producing transitions in the presence of a stimulating photon of the same energy that is provided by the auxiliary light source. A moderate overlap, e.g., about 17-19% overlap, between electron and hole envelope wave functions has been simulated based upon an experimental device to provide the necessary effect. Seed light from the auxiliary light source, preferably a laser source, is thus amplified via stimulated emission processes in the multiple quantum well region. This provides a form of optical gain following the absorption of broad-spectrum incident photons.

The spectrally concentrated output light can be designed to have constituent wavelengths that are suitable for transmission over optical fiber(s). In a preferred embodiment, the spectral concentrator and laser are coupled via optical elements (waveguide, grating, lens) to a large core optical fiber. Optical coupling of the gain medium and the waveguide is optimized by the large spatial overlay between components. In a preferred embodiment, a concentrator, multiple quantum well and waveguide are a planar integrated structure and output light issues from the edge facets of the waveguide. Low-loss optical lenses or other components commonly employed in optical networks can couple the output from the waveguide into one or more optical fibers.

Preferred embodiments of the invention will now be discussed with respect to the drawings. The drawings may include schematic representations, which will be understood by artisans in view of the general knowledge in the art and the description that follows. Features may be exaggerated in the drawings for emphasis, and features may not be to scale.

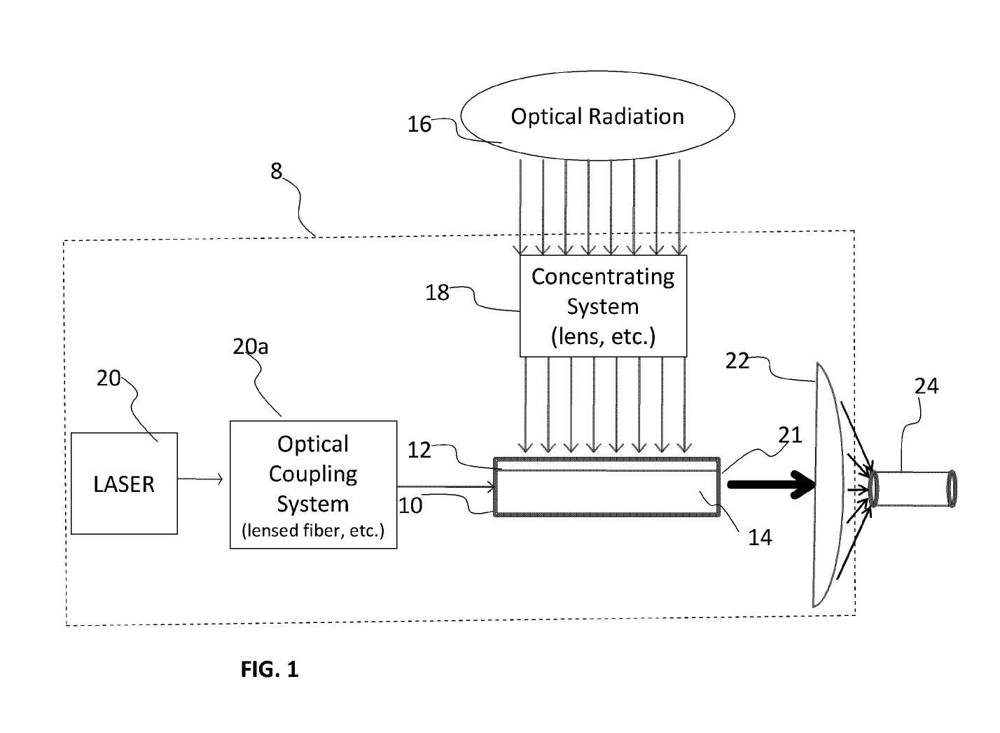

FIG. 1 shows an example optical concentrator device 8 of the invention that includes an integrated crystal active semiconductor structure 10 having a multiple quantum well region 12 and an output waveguide 14. The quantum well region 12 converts broad-spectrum optical radiation into electrical energy in the form of electron-hole pairs and is in an area of the active semiconductor structure where the electric field is small, such as a p or n region, where either the hole or the electron is the majority carrier, or i (intrinsic) region with a counter bias voltage, so that the electron-hole pairs generated are ordinarily not separated and the electrons (holes) accumulate at the bottom (top) of the conduction (valence) band of the well. Experimental devices had multiple quantum wells in the i-region. There are also other ways to make the electric field small, such as the used of intra step quantum wells or quantum wells having a thick intrinsic layer. The quantum well and waveguide active structure is preferably formed from the InGaAsP/InP and InGaN/GaN families of semiconductor materials with bandgaps that can absorb most of the solar spectrum.

Incident radiation 16, e.g., sunlight is focused toward the semiconductor structure 10 by an auxiliary concentrating system 18 such as lenses or mirrors to concentrate the optical radiation incident on the top surface of the semiconductor structure 10. The incident radiation 16 is absorbed by the quantum well region 12 of the concentrator. Optical coupling system 20a directs an auxiliary light source (laser 20) toward the concentrator device 10. The coupled laser light is amplified via a stimulated emission process in the quantum well region 12, which has optical gain as a result the absorption of photon from the sun light. The multiple quantum wells 12 are designed so that photo-generated electrons and holes that accumulate and relax within the multiple quantum well conduction and valence bands have overlapping envelope wave functions, which in turn favor the occurrence of photon-producing transitions in the presence of a stimulating photon of the same energy that is provided by the auxiliary light source. Seed light from the laser source 20 is thus amplified via stimulated emission processes in the multiple quantum well region 12. This provides a form of optical gain following the absorption of broad-spectrum incident photons.

The light concentrating system 18 can be realized by one or more conventional optical components and can also include conventional devices and optical components for efficiently capturing the intensity of the incident radiation 16. The waveguide 14 outputs optical energy of the specific wavelengths to an output facet 21. The optical energy coming out of the output facet 21 is concentrated in a narrow wavelength spectrum, preferably determined to optimize transport in optical fibers. A lens 22 or other suitable optics couples the output optical energy from the device 8 into one or more optical fibers 24, which are preferably large diameter optical fibers and/or fiber bundles that can carry energy to near or remote users and energy output or conversion devices. Conventional multi-mode (MM) fibers with 50-60 um diameter are example large core fibers that can be used. Preferably, a cylindrical (astigmatic) lens integrated with the multimode fiber is used. In a preferred application, the optical radiation is sunlight that is concentrated in a few spectral wavelength regions and out-coupled in the form of stimulated amplified light to the large core fiber.

The concentrated optical output from the device 8 is coupled to the fiber 24 under more relaxed conditions than defined coupling for optical communication systems. The optical output coupling from the spectral concentrator 8 to the optical fiber 24 is more relaxed because a multi-mode coupling is permissible, mode properties are unimportant except for the desirability of minimizing propagation losses, the fiber core size can be much larger than those used in fiber communication, and the maximum power density in fiber is proportional to the cross-sectional area of the fiber core. Additionally, the delivery distance for an optical power system of the invention is likely to be shorter than that used in typical optical communication systems. With transmit power spread over the width, a large core fiber should safely carry large optical powers, e.g., 1 MW/mm².

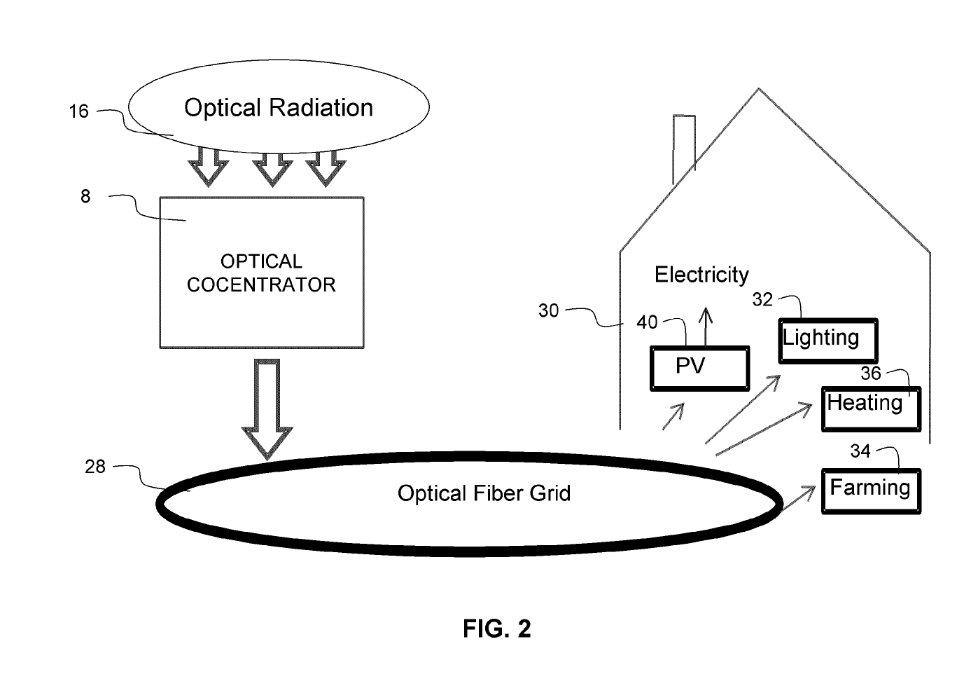

FIG. 2 illustrates an example embodiment optical power system of the invention that includes an optical concentrator device 8 like that shown in FIG. 1. An optical fiber grid 28 communicates concentrated optical energy to a remote user facility 30, such as commercial, agricultural or residential unit. The optical fiber grid 28 can include a distribution system that is comparable to electrical power distribution systems in that some portions of the optical fiber grid 28 can have larger capacities for transmission to an area such as a neighborhood, while a smaller fibers and portions may lead to individual facilities such as the facility 30. Losses in optical fiber are much smaller, of course, than in electrical wires of the comparable cross-sections (electrons interact strongly with each other and with most conducting mediums whereas photons do not interact with each other in free space and in pure dielectrics where they only get scattered or absorbed slowly by the materials). For this reason there will be very low losses in the optical fiber grid 28. At the facility 30, the optical energy can be converted or used in the form of optical energy. Indoor or outdoor lighting 32, for example, can make direct use of optical energy provided via the optical fiber grid 28. Farming 34 might also benefit from direct use of light to provide optical markers that could aid in harvesting and other operations. The optical energy could also be converted to heat for a heating system 36. For example, there are commercially available solar water heater systems. The optical energy can also be converted to electricity by a photovoltaic device 40 such as a solar cell or panel that is normally used to directly convert sunlight into electricity. Such a solar cell or panel can be located at any convenient place within or outside of a structure because the solar panel does not have to be exposed to sunlight. This provides performance advantages such as those discussed above.

The FIG. 2 system provides the separation between the collection of optical radiation and the delivery of optical or electrical energy. That separation of the location of the optical radiation collection plane and the locations where end users make use of the energy via the grid 28 provides great flexibility to determine the amount of energy available per unit time and the end functionality of the use of the optical energy.

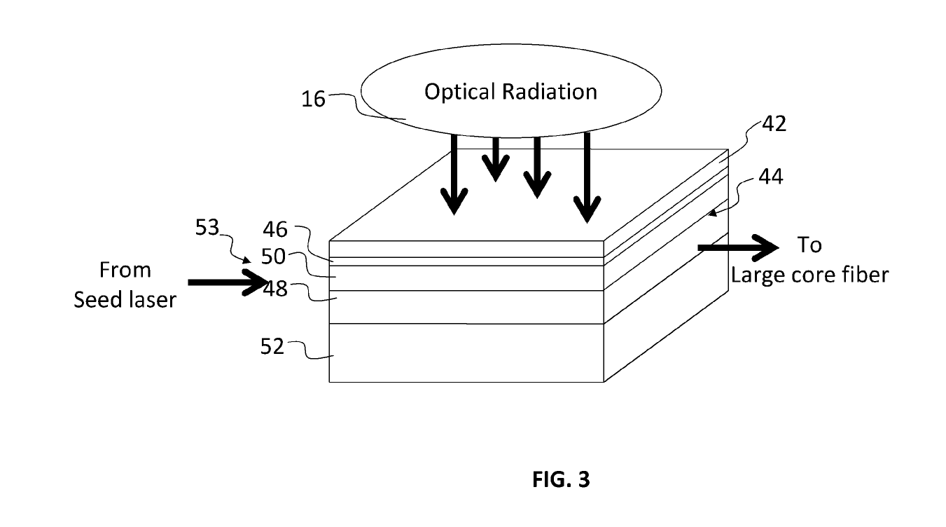

FIG. 3 is a schematic diagram of a preferred embodiment slab waveguide and quantum well concentrator device that could be used in the FIG. 1 device or another device of the invention with different optics. The FIG. 3 device receives optical radiation 16, e.g., solar energy, via the exposed surface of a top cladding layer 42, absorbs the radiation in quantum well region 46 to create electron-hole pairs, and emits concentrated optical energy via a side output facet 44. A quantum well region 46 with a multiple quantum well structure is separated from the core of a slab waveguide 48 by another cladding layer 50. The bottom cladding layer 52 is typically the substrate. A seed laser is coupled into the waveguide layer 48 from input facet 53 and causes stimulated emissions by recombination of electron-hole pairs in multiple quantum well region 46. The photons created by stimulated emission in quantum well region 46 have a narrow spectrum and same momentum as the seed laser so that the seed laser is amplified when it reaches output facet 44 to be collected by a large core fiber.

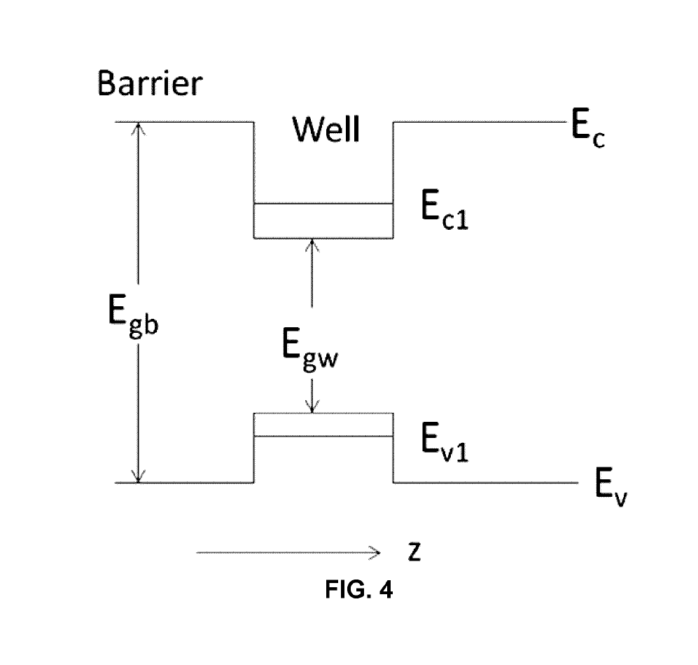

FIG. 4 is an energy band diagram for a quantum well region that can be used to explain the multiple quantum well region 12 of the spectral concentrator 8. Typically a quantum well, as shown in FIG. 3 consists of a barrier region having a high energy bandgap E_{gb} and a well region having low energy bandgap E_{gw} and a width that is close to the electron wavelength. In FIG. 4, Eᵥ denotes the band edge of the valence band, E_{c} denotes that of the conduction band, and the confinement of the carriers inside the well results in confined energy levels as shown in FIG. 4. In typical multiple quantum well designs for solar cell applications [see, e.g., J. M. Olson, D. J. Friedman and Sarah Kurtz, “High-Efficiency III-V Multijunction Solar Cells”, Chap. 9, in Handbook of Photovoltaic Science and Engineering] the multiple quantum wells are placed in the intrinsic region of a p-i-n region such that the electric field at the intrinsic region will separate the electron-hole pairs generated by photoabsorption of a photon across the bandgap (in the process electron makes a transition from the energy level in the valence band to that in the conduction band, giving rise to the electron-hole pair). Photons with larger energy will generate electrons with energy higher than E_{c1} (and holes with energy lower than Eᵥ₁) and they relax to the respective energy levels (E_{c1} and Eᵥ₁) via the emission of phonons (heat).

The energy separation of E_{c1} and Eᵥ₁ can be tuned by the material composition of the well and the barrier, as well as the width of the well region. In the example here, photons with energy larger than this energy separation can be absorbed and the electron and hole created will relax to the E_{c1} and Eᵥ₁ respectively via the emission of phonons, the drift of the carriers under the electric field are responsible for current in the external circuit.

The multiple quantum well region 12 of FIG. 1 locates the quantum wells where the electric field is very small, for instance, at the p or n region where either the hole or the electron is the majority carrier, or at the intrinsic region with a counter bias voltage, so that the electron-hole pairs generated are ordinarily not separated and the electrons and holes accumulate at E_{c1} and Eᵥ₁ respectively. A low electric field is also possible by having a thick i-layer. The electron and hole wave function overlap by designing the quantum wells with intrasteps, and the overlap can be tuned with a small bias voltage. At high concentration, the absorption rate is reduced. A steady state can be reached when the delay processes balance the generation process. Several decay processes can occur, namely (a) the spontaneous decay (emitting a photon with energy close to (E_{c1}-Eᵥ₁), (b) multiple phonon emission, (c) Auger recombination, and (d) stimulated decay in the presence of another laser photon of same energy which is close to (E_{c1}-Eᵥ₁). It is the photons generated in the process (d) that are of interest because the energy distribution of the resulting photons are much narrower in spectral width and their propagation direction is close to that of the seed laser photons. For these reasons, it is easier to collect them into an optical waveguide such as optical fiber(s) 24 or the optical grid 28.

The goal is efficient optical energy collection and not at high speed as in the case of optical communications, so the design rules for the quantum wells in the optical spectral concentrator shown in FIG. 1 are much more relaxed and embodiments can exploit the designs for collections of photons with energy around (E_{c1}-Eᵥ₁). The quantum wells can be designed with respective levels such that different (E_{c1}-Eᵥ₁)'s can be resulted for optimizing the optical distribution around that energy.

Previous research by the inventor and colleagues at the University of California at San Diego has provided multiple quantum wells for optical communications such as low threshold lasers and efficient electroabsorption modulators with high saturation optical power [See, e.g., Yu et al, U.S. Pat. No. 7,095,542, issued on Aug. 22, 2006 and entitled Electroabsorption Modulator Having a Barrier Inside a Quantum Well; and J. X. Chen, Y. Wu, W. X. Chen, I. Shubin, A. Clawson, W. S. C. Chang, P. K. L. Yu, “High-power intrastep quantum well electroabsorption modulator using single-sided large optical cavity waveguide,” IEEE Photonics Technology Letters, Vol. 16 (2), pp. 440-2 (2004)]. This intra-step-barrier multiple quantum well work of Yu et al. included multiple quantum well designs enhance the saturation optical power of an electroabsorption modulator. That design facilitated the separation of electron-hole pairs in the presence of a strong electric field.

Electron-hole pairs accumulated at the quantum well region relax and respectively form electron envelope and hole envelope wave functions at the conduction and valence bands. For the region 12 in the concentrator 8, an important feature of the quantum well design ensures some overlap between these envelope wave functions so that there is a reasonably high probability for radiative transitions to occur with a photon generated in the presence of a stimulating photon of the same energy.

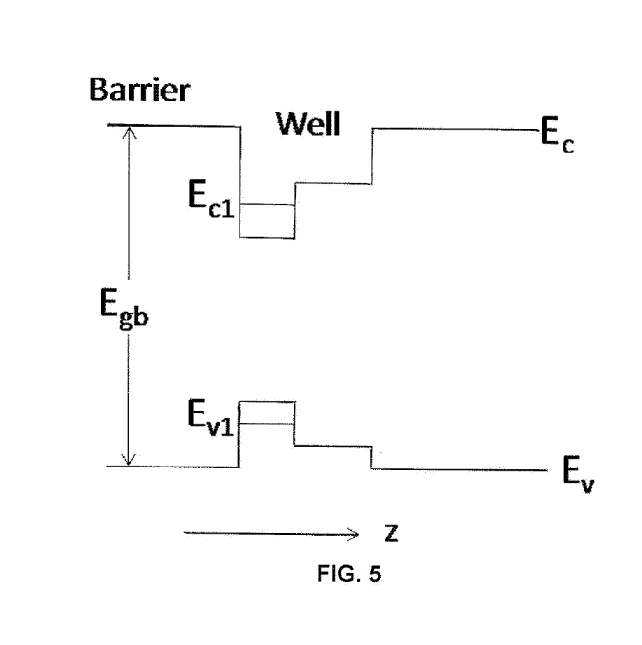

This is different from the prior intra-step-barrier multiple quantum well work of Yu et al. The present quantum well region is located where the electric field is very small, for example, at the p or n region where either the hole or the electron is the majority carrier and the voltage drop over the region is small, the electrons and holes generated are ordinarily not separated, and the electrons and holes accumulate at the conduction and valence bands respectively. This is shown in the FIG. 5 diagram, where the location of the intra-energy-step inside the well is opposite to that of the prior intra-step-barrier multiple quantum well work of Yu et al, so that even in the presence of the electric field (toward the +z direction), the electron and the hole envelope wave functions will become more concentrated in the inner well region. This extra stability gives rise to a higher affinity between the electron-hole pairs and thus a higher probability for radiative transitions to occur which helps the operation of the optical spectral concentrator. Materials selected for the quantum well region 12 and waveguide 14 should provide low loss and high efficiency photon concentrator at the specific wavelengths of interest and be highly transparent to the substrate of the concentrator. Low or zero bias operation is possible.

### Experimental Devices

An experimental multiple quantum well/waveguide structure was formed. The semiconductor waveguides with multiple quantum wells were designed to effectively amplify a seed laser (1470 nm) signal by converting solar energy absorbed by the quantum wells into electron and hole pairs and then allowing them to recombine and emit photons coherent with the seed laser. Stimulated emission due to the seed laser is important for effective amplification. The quantum wells were designed with intra steps that allow spatial separation between electrons and holes in order to prevent spontaneous emission.

An example device is grown epitaxially on an n-type InP substrate. The waveguide is a slab waveguide with bandgap wavelength of 1.1 μm. There are eight quantum wells which are designed to emit wavelength of 1468 nm. The complete structure is listed in Table 1.

TABLE 1
SAMPLE (OR EXAMPLE OF) SOLAR CONCENTRATOR LAYER STRUCTURE

| Layer | | | | | | Bandgap wavelength | |
|---|---|---|---|---|---|---|---|
| # | Material | Purpose | Thickness | | Doping (cm⁻³) | (energy) | Index |
| 1 | InGaAs | high dopant | 50 | nm | p, >10\hat{ }19 | | |
| | | concentration, low | | | | | |
| | | ohmic resistance | | | | | |
| 2 | InP | buffer | 0.7 | um | p, 5 × 10\hat{ }17 | | n = 3.15 |
| 3 | InGaAsP | graded bandgap | 50 | nm | p, 5 × 10\hat{ }17 | 1.191 um (1.04 eV) | n = 3.37 |
| 4 | InGaAsP | Zn diffusion | 50 | nm | undoped | 1.191 um (1.04 eV) | n = 3.38 |
| | | stopper, graded | | | | | |
| | | bandgap | | | | | |
| 5 | InGaAsP | QWs | 144 | nm | undoped | Effective λ = 1468 nm | n = 3.506 |
| | | | 8 × | | | 1.572 um/1.425 um/1.107 um | |
| | | | 5 nm/6 nm/7 nm | | | | |
| 6 | InGaAsP | spacer | 7 | nm | undoped | 1.107 um | |
| 7 | InP | etch stop, | 100 | nm | n, 1 × 10\hat{ }18 | | n = 3.15 |
| | | concentration | | | | | |
| | | reducer, lattice | | | | | |
| | | matching layer | | | | | |
| 8 | InGaAsP | n-layer, waveguide | 0.53 | m | n, 3 × 10\hat{ }18 | 1.142 um (1.086 eV) | n = 3.34 |
| | | layer | | | | | |
| 9 | InGaAsP | waveguide layer | 1.1 | m | undoped | 1.142 um (1.086 eV) | n = 3.35 |
| 10 | InP | buffer layer | 0.25 | m | undoped | | n = 3.17 |
| 11 | InP | substrate | ~250 | m | n | | |

### Fabrication

Electrical contacts were fabricated for the experimental device. Three layers of masks were drawn for photolithography. The first mask consisted of 1000 μm by 1000 μm squares separated from each other by 150 μm which serve as a mask for wet chemical mesa etch to electrically isolate the top conducting p-type layers. The second mask consisted of 990 μm by 990 μm squares for a 100 nm thick indium-tin-oxide (ITO, a conducting, transparent material) by sputtering which are situated on top of the mesas, offset and centered within each 1000 μm square leaving 5 μm from each edge. The third mask was for metal (Pd/Ti/Pd/Au) deposition by evaporation and consisted of six square 100 μm by 100 μm contact pads per mesa for one portion and another portion having the six square 100 μm by 100 μm contact pads per mesa as well as 2 μwide connecting mesh. The wafer was mechanically thinned by lapping to about 150 μm before Ti/Au was sputtered on the back side for re-contact. The wafer was then cleaved into one row of mesas for optical measurement.

### Measurement

The solar concentrator device was measured electrically and optically. A 1310 nm pump laser and 1470 nm seed laser were coupled by a 90/10 coupler into a side facet of the experimental slab waveguide with a bias applied between the top and bottom contacts and collected with a multi-mode optical fiber and provided to a optical spectrum analyzer. Electrical (current versus voltage or I-V) measurement was made to determine the photocurrent due to different light sources, which is a good estimate of the relative absorption of each light source. and the results are in TABLE 2.

TABLE 2
PHOTOCURRENT DUE TO DIFFERENT LIGHT SOURCES FROM
I-V MEASUREMENTS.

| Light source | Photocurrent at zero bias | |
|---|---|---|
| Room light | −300 | nA |
| Fiber lamp | −1 | mA |
| 1310 nm “pump” laser | −5.8 | mA |
| 1470 nm “seed” laser | −198 | μA |
| Everything together | −6 | mA |

Optical (power versus wavelength) measurement was conducted to determine the amplification of the seed laser due to the pump laser source. Another optical measurement was made to determine the amplification of the seed laser due to a fiber lamp with a halogen bulb, a white light source. Optical measurement (power versus wavelength) of solar concentrator device using a 1310 nm laser at 50 mW as a pumping source to amplify 1470 nm seed laser signal, showing an amplification up to 8 dB at wavelengths around 1470 nm. The measurements (power versus wavelength) of the solar concentrator device using a fiber lamp (white light source) as a pumping source to amplify 1470 nm seed laser signal showed an amplification up to 6.8 dB at wavelengths around 1470 nm.

While specific embodiments of the present invention have been shown and described, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. An integrated optical spectral concentrator device, comprising:
a waveguide; and
an active region including a quantum well region in a region of small electric field, the quantum well region being configured to convert broad band optical radiation into electron-hole pairs and amplify seed laser light of a predetermined wavelength range through the contribution of photons produced by stimulated emissions in the quantum well region into optical energy of a predetermined band.

2. The device of claim 1, wherein said quantum well region comprises a multiple quantum well region and wherein said multiple quantum well region is configured such that electron-hole pairs accumulated at the quantum well region relax and respectively form electron envelope and hole envelope wave functions at the conduction and valence bands, and the multiple quantum well region is configured to provide overlap between these envelope wave functions so that there is a high probability for radiative transitions to occur with a photon generated in the presence of a stimulating photon of the same energy.

3. The device of claim 1, wherein said quantum well region comprises a multiple quantum well region and further comprising:
electrodes for biasing the active region;
optics for directing seed laser light to the active region; and
optics for coupling light output from the device to an optical fiber or optical fiber network.

4. An optical power distribution system, comprising:
an optical device in accordance with claim 3; and
an optical fiber for transporting the optical energy of the predetermined band.

5. The system of claim 4, further comprising end device for receiving and using the optical energy of the predetermined band.

6. The system of claim 5, wherein the end device comprises a photovoltaic device that converts the optical energy of the predetermined band into electrical energy.

7. The system of claim 6, wherein the end device comprises a solar cell.

8. The system of claim 5, wherein the end device comprises one of a heating device or a lighting device.

9. The device of claim 1, wherein said active region is formed from one of the InGaAsP/InP and InGaN/GaN families of semiconductor materials.

10. The device of claim 9, wherein said quantum well region comprises a multiple quantum well region and wherein the bandgaps of the multiple quantum wells cover a majority of the solar spectrum.

11. The device of claim 9, wherein said quantum well region comprises a multiple quantum well region and wherein the bandgaps of the multiple quantum wells cover a majority of the solar spectrum

12. The system of claim 3, wherein the optical fiber or optical fiber network comprises a large core multi-mode optical fiber.

13. The system of claim 12, wherein the large core multi-mode optical fiber is configured to transport 1 MW/mm².

14. The system of claim 3, wherein the active region and waveguide are configured to output the optical energy of the predetermined band from an edge facet.

15. The system of claim 1, wherein the waveguide comprises a slab waveguide.

16. The device of 1 wherein multiple quantum well regions include an intra-step barrier to concentrate electron and hole envelope wave functions within the inner well region.

17. A method for concentrating optical radiation, the method comprising;
receiving optical radiation in a quantum well region that will convert received optical radiation into electron and hole pairs;
receiving narrow band seed optical energy;
combining the narrow band seed optical energy with recombined electron and hole pairs in the quantum well region to produce narrow band amplified optical energy; and
outputting the narrow band amplified optical energy.

18. The method of claim 17, further comprising coupling the narrow band amplified optical energy into a large diameter multi mode optical fiber.

19. The method of claim 17, further comprising delivering the narrow band amplified optical energy to a remote location.

20. The method of claim 19, further comprising converting the optical energy at the remote location into electrical energy.

21. An optical concentrator device comprising:
waveguide means for confining optical energy; and
quantum well means for receiving narrow band seed optical energy and optical radiation, for converting the optical radiation into electron and hole pairs and for combining the narrow band seed optical energy with recombined electron and hole pairs in the quantum well region to produce narrow band amplified optical energy.

22. An optical concentrator device comprising:
waveguide means for confining optical energy; and
quantum well means for converting optical radiation into electron and hole pairs and permitting stimulated decay in the presence of a seed laser photon of energy to generate photons in the much narrower spectral width of the seed laser in a propagation direction is close to that of the incident laser photons
